(19) United States
(12) Patent Application Publication
(10) Pub. No.: US 2019/0147824 A1
(43) Pub. Date: May 16, 2019

(54) GATE DRIVING CIRCUIT AND DISPLAY DEVICE HAVING THE SAME

(71) Applicant: SAMSUNG DISPLAY CO., LTD., Yongin-si (KR)

(72) Inventors: Hyunwook Lee, Asan-si (KR); Jae-Hyun Park, Yongin-si (KR); Jaemin Seong, Suwon-si (KR)

(21) Appl. No.: 16/132,619

(22) Filed: Sep. 17, 2018

(30) Foreign Application Priority Data
Nov. 10, 2017 (KR) 10-2017-0149860

(51) Int. Cl. G09G 3/36; G11C 19/28

(52) U.S. Cl. CPC G09G 3/3688; G11C 19/287; G09G 2300/0809; G09G 2310/0286; G09G 2310/08

(57) ABSTRACT

A gate driving circuit includes a plurality of driving stages applying gate signals to a plurality of gate lines of a display panel and a plurality of ripple discharge circuits discharging a ripple voltage of the gate lines. A k-th driving stage (where k is a natural number greater than 1), among the driving stages, outputs a k-th gate signal to a k-th gate line, among the gate lines, in synchronization with a first clock signal, and a k-th ripple discharge circuit, among the ripple discharge circuits, corresponding to the k-th driving stage discharges the ripple voltage of the k-th gate line to a first voltage in synchronization with a second clock signal complementary to the first clock signal.

### CROSS-REFERENCE TO RELATED APPLICATION

This U.S. non-provisional patent application claims priority under 35 U.S.C. § 119 to Korean Patent Application No. 10-2017-0149860, filed on Nov. 10, 2017, the disclosure of which is incorporated by reference herein in its entirety.

### TECHNICAL FIELD

Exemplary embodiments of the inventive concept relate to a gate driving circuit driving gate lines of a display panel and a display device having the gate driving circuit.

### DISCUSSION OF RELATED ART

A display device includes gate lines, data lines, and pixels each being connected to a corresponding gate line of the gate lines and a corresponding data line of the data lines. The display device includes a gate driving circuit applying gate signals to the gate lines and a data driving circuit applying data signals to the data lines.

The gate driving circuit includes a shift register including driving stage circuits (hereinafter, referred to as driving stages). The driving stages output corresponding gate signals to the gate lines. Each of the driving stages includes transistors connected to one another.

### SUMMARY

According to an exemplary embodiment of the inventive concept, a gate driving circuit may include a plurality of driving stages applying gate signals to a plurality of gate lines of a display panel and a plurality of ripple discharge circuits discharging a ripple voltage of the gate lines. A k-th driving stage (where k is a natural number greater than 1), among the plurality of driving stages, outputs a k-th gate signal to a k-th gate line, among the plurality of gate lines, in synchronization with a first clock signal. A k-th ripple discharge circuit, among the plurality of ripple discharge circuits, corresponding to the k-th driving stage discharges a ripple voltage of the k-th gate line to a first voltage in synchronization with a second clock signal complementary to the first clock signal.

The k-th ripple discharge circuit may discharge the ripple voltage of the k-th gate signal to the first voltage when the second clock signal has a first level and the k-th gate signal is higher than a level of the first voltage.

The k-th ripple discharge circuit may include a first switching unit electrically connecting the k-th gate line to a first node in response to the second clock signal, a second switching unit electrically connecting the first node and a second node in response to a signal of the first node, and a capacitor connected between the second node and a node to which the first voltage is applied.

The k-th ripple discharge circuit may include a first transistor connected between the k-th gate line and a first node and including a control electrode receiving the second clock signal, a second transistor connected between the first node and a second node and including a control electrode connected to the first node, and a capacitor connected between the second node and a node to which the first voltage is applied.

The k-th ripple discharge circuit may include a first switching unit electrically connecting the k-th gate line to a first node in response to the second clock signal, and a second switching unit discharging the first node to the first voltage in response to a signal of the first node.

The k-th driving stage may further receive a (k−1)th carry signal from a (k−1)th driving stage, a (k+1)th carry signal from a (k+1)th driving stage, a (k+2)th carry signal from a (k+2)th driving stage, and a second voltage, and may further output a k-th carry signal.

The k-th driving stage may include a first output circuit outputting the first clock signal as the k-th gate signal in response to a signal of a first node during a k-th clock period of the first clock signal and a second output circuit outputting the first clock signal as the k-th carry signal in response to the signal of the first node during the k-th clock period of the first clock signal.

The k-th driving stage may further include a control circuit applying the (k−1)th carry signal to the first node in response to the (k−1)th carry signal and discharging the first node to the second voltage in response to the (k+2)th carry signal, a discharge hold circuit applying the first clock signal to a second node in response to the first clock signal and the k-th carry signal, a first discharge circuit discharging the first node and the second node to the second voltage in response to the (k−1)th carry signal, a second discharge circuit discharging the k-th carry signal to the second voltage in response to a signal of the second node, a third discharge circuit discharging the k-th gate signal to the first voltage in response to the signal of the second node, and a pull-down circuit discharging the k-th carry signal to the second voltage in response to the (k+1)th carry signal.

The k-th driving stage may further include a control circuit applying the (k−1)th carry signal to the first node in response to the (k−1)th carry signal and discharging the first node to the second voltage in response to the (k+2)th carry signal, a discharge hold circuit applying the first clock signal to a second node in response to the first clock signal and the k-th gate signal, a first discharge circuit discharging the first node and the second node to the second voltage in response to the (k−1)th carry signal, a second discharge circuit discharging the k-th carry signal to the second voltage in response to a signal of the second node, a third discharge circuit discharging the k-th gate signal to the first voltage in response to the signal of the second node, and a pull-down circuit discharging the k-th gate signal to the second voltage in response to the (k+1)th carry signal.

According to an exemplary embodiment of the inventive concept, a gate driving circuit may include a plurality of driving stages applying gate signals to a plurality of gate lines of a display panel. A k-th driving stage (where k is a natural number greater than 1), among the plurality of driving stages, may include a driving circuit outputting a k-th gate signal to a k-th gate line, among the plurality of gate lines, in synchronization with a first clock signal and a ripple discharge circuit discharging a ripple voltage of the k-th gate line to a first voltage in synchronization with a second clock signal that is complementary to the first clock signal.

The ripple discharge circuit may discharge the ripple voltage of the k-th gate line to the first voltage when the second clock signal has a first level and a voltage of the k-th gate line is higher than a level of the first voltage.

The ripple discharge circuit may include a first switching unit electrically connecting the k-th gate line to a first node in response to the second clock signal, a second switching unit electrically connecting the first node to a second node in response to a signal of the first node, and a capacitor connected between the second node and a node to which the first voltage is applied.

The ripple discharge circuit may include a first transistor connected between the k-th gate line and a first node and including a control electrode receiving the second clock signal, a second transistor connected between the first node and a second node and including a control electrode connected to the first node, and a capacitor connected between the second node and a node to which the first voltage is applied.

The driving circuit may include a first output circuit outputting the first clock signal as the k-th gate signal in response to a signal of a first node during a k-th clock period of the first clock signal, and a second output circuit outputting the first clock signal as a k-th carry signal in response to the signal of the first node during the k-th clock period of the first clock signal.

The driving circuit may further include a control circuit applying one of the first clock signal and a second voltage to the first node in response to the first clock signal, a (k−1)th carry signal, and a (k+2)th carry signal, a discharge hold circuit applying the first clock signal to a second node in response to the first clock signal and the k-th carry signal, a first discharge circuit discharging the first node and the second node to the second voltage in response to the (k−1)th carry signal, a second discharge circuit discharging the k-th carry signal to the second voltage in response to a signal of the second node, a third discharge circuit discharging the k-th gate signal to the first voltage in response to the signal of the second node, and a pull-down circuit discharging the k-th carry signal to the second voltage in response to a (k+1)th carry signal.

The driving circuit may further include a control circuit applying one of the first clock signal and a second voltage to the first node in response to the first clock signal, a (k−1)th carry signal, and a (k+2)th carry signal, a discharge hold circuit applying the first clock signal to a second node in response to the first clock signal and the k-th gate signal, a first discharge circuit discharging the first node and the second node to the second voltage in response to the (k−1)th carry signal, a second discharge circuit discharging the k-th carry signal to the second voltage in response to a signal of the second node, a third discharge circuit discharging the k-th gate signal to the second voltage in response to the signal of the second node, and a pull-down circuit discharging the k-th gate signal to the second voltage in response to a (k+1)th carry signal.

According to an exemplary embodiment of the inventive concept, a display device may include a display panel including a plurality of gate lines, a plurality of data lines, and a plurality of pixels each being connected to a corresponding gate line of the gate lines and a corresponding data line of the data lines, a gate driving circuit including a plurality of driving stages outputting gate signals to the plurality of gate lines, and a data driving circuit driving the plurality of data lines. A k-th driving stage (where k is a natural number greater than 1), among the plurality of driving stages, includes a driving circuit outputting a k-th gate signal to a k-th gate line, among the plurality of gate lines, in synchronization with a first clock signal, and a ripple discharge circuit discharging a ripple voltage of the k-th gate line to a first voltage in synchronization with a second clock signal that is complementary to the first clock signal.

The ripple discharge circuit may discharge the ripple voltage of the k-th gate line to the first voltage when the second clock signal has a first level and the voltage of the k-th gate line is higher than a level of the first voltage.

The ripple discharge circuit may include a first switching unit electrically connecting the k-th gate line to a first node in response to the second clock signal, a second switching unit electrically connecting the first node to a second node in response to a signal of the first node, and a capacitor connected between the second node and a node to which the first voltage is applied.

The ripple discharge circuit may include a first transistor connected between the k-th gate line and a first node and including a control electrode receiving the second clock signal, a second transistor connected between the first node and a second node and including a control electrode connected to the first node, and a capacitor connected between the second node and a node to which the first voltage is applied.

### BRIEF DESCRIPTION OF THE DRAWINGS

The above and other features of the inventive concept will become readily apparent by describing in detail exemplary embodiments thereof with reference to the accompanying drawings.

FIG. 1 is a plan view showing a display device according to an exemplary embodiment of the inventive concept.

FIG. 2 is a timing diagram showing signals generated by the display device of FIG. 1 according to an exemplary embodiment of the inventive concept.

FIG. 3 is a block diagram showing a gate driving circuit of FIG. 1 according to an exemplary embodiment of the inventive concept.

FIG. 4 is a circuit diagram showing a driving stage of FIG. 3 according to an exemplary embodiment of the inventive concept.

FIG. 5 is a circuit diagram showing a ripple discharge circuit of FIG. 3 according to an exemplary embodiment of the inventive concept.

FIG. 6 is a timing diagram showing an operation of the driving stage of FIG. 4 and the ripple discharge circuit of FIG. 5 according to an exemplary embodiment of the inventive concept.

FIG. 7 is a circuit diagram showing a driving stage according to an exemplary embodiment of the inventive concept.

FIG. 8 is a block diagram showing a gate driving circuit according to an exemplary embodiment of the inventive concept.

FIG. 9 is a circuit diagram showing a ripple discharge circuit according to an exemplary embodiment of the inventive concept.

FIG. 10 is a block diagram showing a gate driving circuit according to an exemplary embodiment of the inventive concept.

FIG. 11 is a circuit diagram showing a driving stage according to an exemplary embodiment of the inventive concept.

FIG. 12 is a circuit diagram showing a driving stage according to an exemplary embodiment of the inventive concept.

FIG. 13 is a block diagram showing a gate driving circuit according to an exemplary embodiment of the inventive concept.

FIG. 14 is a circuit diagram showing a driving stage according to an exemplary embodiment of the inventive concept. and

FIG. 15 is a circuit diagram showing a driving stage according to an exemplary embodiment of the inventive concept.

### DETAILED DESCRIPTION OF THE EMBODIMENTS

Exemplary embodiments of the inventive concept provide a gate driving circuit with increased reliability.

Exemplary embodiments of the inventive concept provide a display device having the gate driving circuit with increased reliability.

Exemplary embodiments of the inventive concept will be described more fully hereinafter with reference to the accompanying drawings. Like reference numerals may refer to like elements throughout this application.

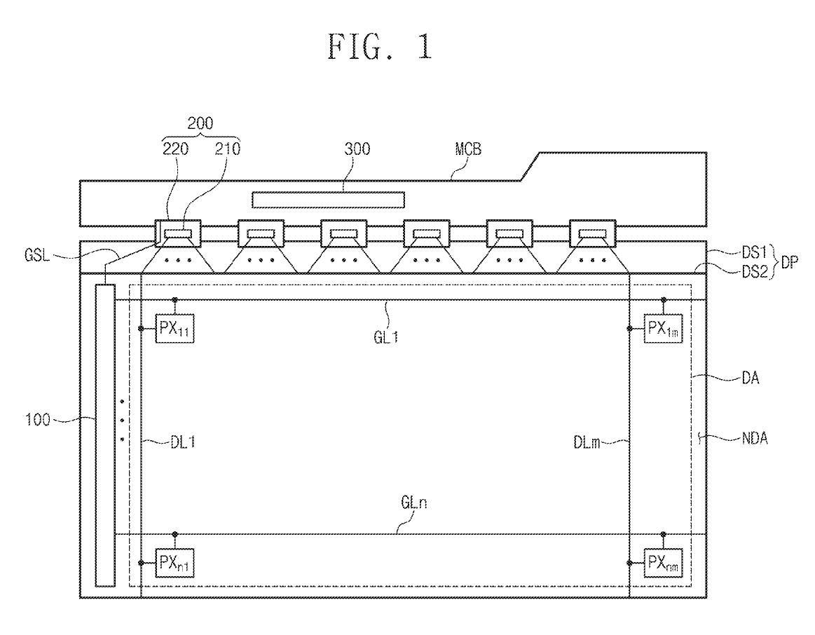

FIG. 1 is a plan view showing a display device according to an exemplary embodiment of the inventive concept.

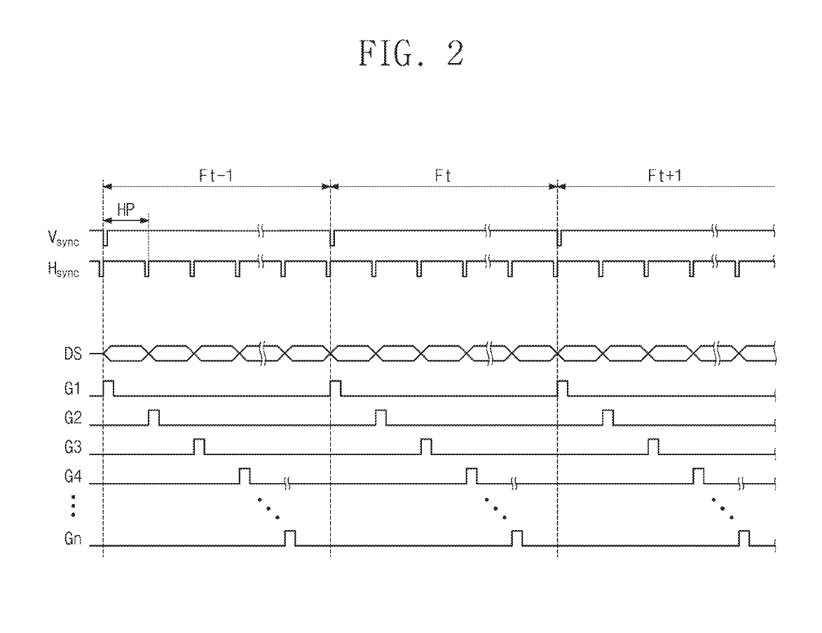

FIG. 2 is a timing diagram showing signals generated by the display device of FIG. 1 according to an exemplary embodiment of the inventive concept.

Referring to FIGS. 1 and 2, the display device according to the present exemplary embodiment includes a display panel DP, a gate driving circuit 100, a data driving circuit 200, and a driving controller 300.

The display panel DP may be one of various display panels, such as a liquid crystal display panel, an organic light emitting display panel, an electrophoretic display panel, an electrowetting display panel, etc., but is not limited thereto. In the present exemplary embodiment, the display panel DP may be a liquid crystal display panel. For example, a liquid crystal display including the liquid crystal display panel may further include a polarizer and a backlight unit.

The display panel DP includes a first substrate DS1 and a second substrate DS2 spaced apart from the first substrate DS1. In a case that the display panel DP is the liquid crystal display panel, the display panel DP further includes a liquid crystal layer interposed between the first substrate DS1 and the second substrate DS2. When viewed in a plan view, the display panel DP includes a display area DA in which a plurality of pixels PX11 to PXnm are arranged and a non-display area NDA surrounding the display area DA.

The display panel DP includes a plurality of gate lines GL1 to GLn arranged on the first substrate DS1 and a plurality of data lines DL1 to DLm crossing the gate lines GL1 to GLn. The gate lines GL1 to GLn are connected to the gate driving circuit 100. The data lines DL1 to DLm are connected to the data driving circuit 200.

FIG. 1 shows some of the gate lines GL1 to GLn and some of the data lines DL1 to DLm. FIG. 1 also shows some the pixels PX11 to PXnm. Each of the pixels PX11 to PXnm is connected to a corresponding one of the gate lines GL1 to GLn and a corresponding one of the data lines DL1 to DLm.

The pixels PX11 to PXnm are divided into a plurality of groups depending on a color displayed therethrough. Each of the pixels PX11 to PXnm may display one of primary colors. The primary colors may include a red color, a green color, and a blue color, but are not limited thereto. For example, the primary colors may further include a white color, a yellow color, a cyan color, etc.

The gate driving circuit 100 and the data driving circuit 200 receive control signals from the driving controller 300. The driving controller 300 may be mounted on a main circuit board MCB. The driving controller 300 receives image data and the control signals from an external graphic control circuit. The control signals may include a vertical synchronization signal Vsync distinguishing frame periods Ft−1, Ft, and Ft+1, a horizontal synchronization signal Hsync distinguishing horizontal periods HP, a data enable signal maintained in a high level during a period, in which data is output, to indicate a data input period, and clock signals.

The gate driving circuit 100 generates gate signals G1 to Gn based on a control signal (hereinafter, referred to as a “gate control signal”) received through a signal line GSL from the driving controller 300 during the frame periods Ft−1, Ft, and Ft+1, and outputs the gate signals G1 to Gn to the gate lines GL1 to GLn. The gate signals G1 to Gn are sequentially output to correspond to the horizontal periods HP. The gate driving circuit 100 may be substantially simultaneously formed with the pixels PX11 to PXnm through a thin film process. For instance, the gate driving circuit 100 may be mounted on the non-display area NDA in an oxide semiconductor TFT gate driver circuit (OSG) form.

FIG. 1 shows one gate driving circuit 100 connected to left ends of the gate lines GL1 to GLn as a representative example, but is not limited thereto. In an exemplary embodiment of the inventive concept, the display device may include two gate driving circuits. One of the two gate driving circuits may be connected to left ends of the gate lines GL1 to GLn, and the other of the two gate driving circuits may be connected to right ends of the gate lines GL1 to GLn. Further, one of the two gate driving circuits may be connected to odd-numbered gate lines, and the other of the two gate driving circuits may be connected to even-numbered gate lines.

The data driving circuit 200 generates grayscale voltages corresponding to the image data provided from the driving controller 300 based on a control signal (hereinafter, referred to as a “data control signal”) received from the driving controller 300. The data driving circuit 200 outputs the grayscale voltages to the data lines DL1 to DLm as data voltages DS.

The data voltages DS output from the data driving circuit 200 may include positive data voltages having a positive value with respect to a common voltage and/or negative data voltages having a negative value with respect to the common voltage. Among the data voltages DS applied to the data lines DL1 to DLm during each of the horizontal periods HP, some data voltages have the positive polarity, and the other data voltages have the negative polarity. The polarity of the data voltages DS may be inverted every one or more frame periods Ft−1, Ft, and Ft+1 to prevent liquid crystals from burning or deteriorating. The data driving circuit 200 may generate the data voltages DS, which may be inverted in response to an inversion signal.

The data driving circuit 200 includes a driving chip 210 and a flexible printed circuit board 220 on which the driving chip 210 is mounted. Each of the driving chip 210 and the flexible printed circuit board 220 may be provided in a plural number. The flexible printed circuit board 220 electrically connects the main circuit board MCB to the first substrate DS1. The driving chips 210 apply the data voltages DS to corresponding data lines of the data lines DL1 to DLm.

FIG. 1 shows the data driving circuit 200 provided in a chip-on-film (COF) manner as a representative example. According to an exemplary embodiment of the inventive concept, the data driving circuit 200 may be disposed in the non-display area NDA of the first substrate DS1 in a chip-on-glass (COG) manner.

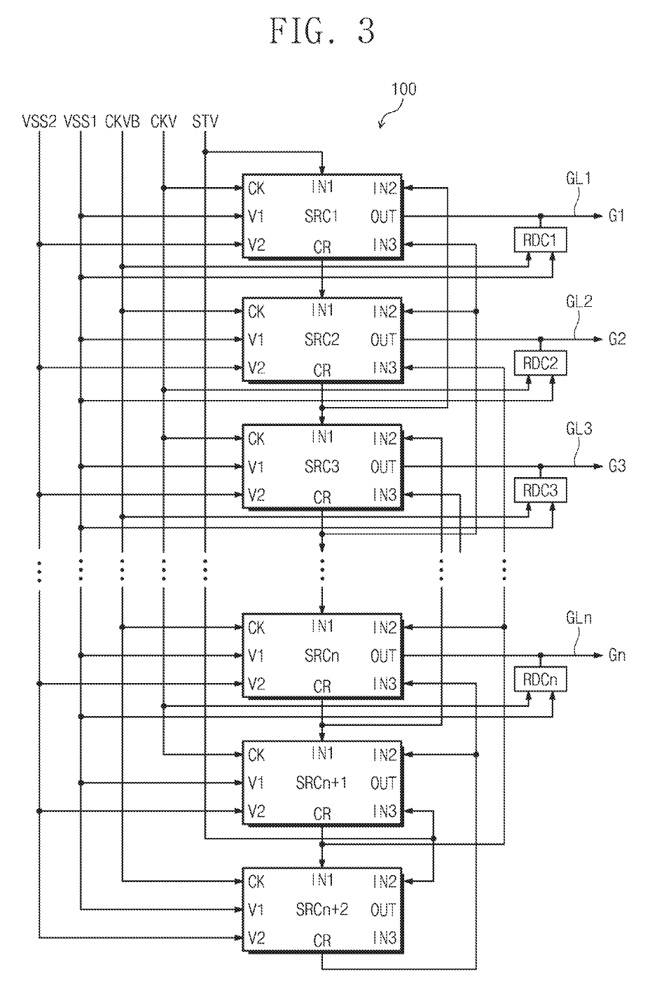

FIG. 3 is a block diagram showing a gate driving circuit of FIG. 1 according to an exemplary embodiment of the inventive concept.

Referring to FIG. 3, the gate driving circuit 100 includes a plurality of driving stages SRC1 to SRCn and dummy driving stages SRCn+1 and SRCn+2. The driving stages SRC1 to SRCn and the dummy driving stages SRCn+1 and SRCn+2 are connected to each other one after another to allow each driving stage to be driven in response to a carry signal output from a previous driving stage and a carry signal output from a next driving stage.

Each of the driving stages SRC1 to SRCn receives a clock signal (a first clock signal CKV or a second clock signal CKVB), a first ground voltage VSS1, and a second ground voltage VSS2 from the driving controller 300 shown in FIG. 1. The first ground voltage VSS1 and the second ground voltage VSS2 may be referred to as a first voltage and a second voltage, respectively. The driving stage SRC1 and the dummy driving stages SRCn+1 and SRCn+2 further receive a start signal STV.

In the present exemplary embodiment, the driving stages SRC1 to SRCn are connected to the gate lines GL1 to GLn, respectively. The driving stages SRC1 to SRCn apply a corresponding gate signal to the gate lines GL1 to GLn, respectively. In the present exemplary embodiment, the gate lines connected to the driving stages SRC1 to SRCn may be odd-numbered gate lines or even-numbered gate lines among the gate lines GL1 to GLn.

Each of the driving stages SRC1 to SRCn and the dummy driving stages SRCn+1 and SRCn+2 includes input terminals IN1, IN2, and IN3, an output terminal OUT, a carry terminal CR, a clock terminal CK, a first voltage terminal V1, and a second voltage terminal V2.

The output terminal OUT of each of the driving stages SRC1 to SRCn is connected to a corresponding gate line of the gate lines GL1 to GLn. The gate signals generated by the driving stages SRC1 to SRCn are applied to the gate lines GL1 to GLn through the output terminals OUT.

The carry terminal CR of each of the driving stages SRC1 to SRCn is electrically connected to a first input terminal IN1 of the next driving stage. In addition, the carry terminal CR of each of the driving stages SRC2 to SRCn is connected to the previous driving stage. For instance, the carry terminal CR of a k-th driving stage SRCk (where “k” is a natural number greater than 2) among the driving stages SRC1 to SRCn is connected to a second input terminal IN2 of a (k−1)th driving stage and a third input terminal IN3 of a (k−2)th driving stage. The carry terminal CR of each of the driving stages SRC1 to SRCn and the dummy driving stages SRCn+1 and SRCn+2 outputs the carry signal.

The first input terminal IN1 of each of the driving stages SRC2 to SRCn and the dummy driving stages SRCn+1 and SRCn+2 receives the carry signal from the previous driving stage. For instance, the first input terminal IN1 of the k-th driving stage SRCk receives the carry signal output from the (k−1)th driving stage SRCk−1. Among the driving stages SRC1 to SRCn, the first input terminal IN1 of the first driving stage SRC1 receives the vertical start signal STV that starts an operation of the gate driving circuit 100 instead of the carry signal of the previous driving stage.

The second input terminal IN2 of each of the driving stages SRC1 to SRCn receives the carry signal from the carry terminal CR of the next driving stage. The third input terminal IN3 of each of the driving stages SRC1 to SRCn receives the carry signal from a driving stage following the next driving stage. For instance, the second input terminal IN2 of the k-th driving stage SRCk receives the carry signal output from the carry terminal CR of a (k+1)th driving stage SRCk+1. The third input terminal IN3 of the k-th driving stage SRCk receives the carry signal output from the carry terminal CR of a (k+2)th driving stage SRCk+2. According to an exemplary embodiment of the inventive concept, the second input terminal IN2 of each of the driving stages SRC1 to SRCn may be electrically connected to the output terminal OUT of the next driving stage. In addition, the third input terminal IN3 of each of the driving stages SRC1 to SRCn may be electrically connected to the output terminal OUT of the driving stage following the next driving stage.

The second input terminal IN2 of the last driving stage SRCn receives the carry signal output from the carry terminal CR of the dummy driving stage SRCn+1. The third input terminal IN3 of the last driving stage SRCn receives the carry signal output from the carry terminal CR of the dummy driving stage SRCn+2.

The clock terminal CK of each of the driving stages SRC1 to SRCn receives one of the first clock signal CKV and the second clock signal CKVB. The clock terminals CK of the odd-numbered driving stages SRC1, SRC3, . . . , SRCn−1 among the driving stages SRC1 to SRCn receive the first clock signal CKV. The clock terminals CK of the even-numbered driving stages SRC2, SRC4, . . . , SRCn among the driving stages SRC1 to SRCn receive the second clock signal CKVB. The first and second clock signals CKV and CKVB have different phases from each other.

The first voltage terminal V1 of each of the driving stages SRC1 to SRCn receives the first ground voltage VSS1. The second voltage terminal V2 of each of the driving stages SRC1 to SRCn receives the second ground voltage VSS2. The first and second ground voltages VSS1 and VSS2 have different voltage levels from each other. In the present exemplary embodiment, the second ground voltage VSS2 has a voltage level lower than that of the first ground voltage VSS1.

In each of the driving stages SRC1 to SRCn according to the present exemplary embodiment, one of the output terminal OUT, the first input terminal IN1, the second input terminal IN2, the third input terminal IN3, the carry terminal CR, the clock terminal CK, the first voltage terminal V1, and the second voltage terminal V2 may be omitted or other terminals may be added to each of the driving stages SRC1 to SRCn. For instance, one of the first and second voltage terminals V1 and V2 may be omitted. In this case, each of the driving stages SRC1 to SRCn receives only one of the first ground voltage VSS1 and the second ground voltage VSS2. In addition, a connection relation between the driving stages SRC1 to SRCn may be changed.

In the present exemplary embodiment, the gate driving circuit 100 further includes a plurality of ripple discharge circuits RDC1 to RDCn.

The ripple discharge circuits RDC1 to RDCn are connected to the gate lines GL1 to GLn, respectively. The ripple discharge circuits RDC1 to RDCn may discharge a ripple voltage of the gate lines GL1 to GLn.

Each of the ripple discharge circuits RDC1 to RDCn receives the first ground voltage VSS1 and one of the first clock signal CKV and the second clock signal CKVB from the driving controller 300 shown in FIG. 1.

The ripple discharge circuits RDC1 to RDCn correspond to the driving stages SRC1 to SRCn, respectively. The ripple discharge circuits RDC1 to RDCn receive the clock signal complementary to the clock signal applied to a corresponding driving stage of the driving stages SRC1 to SRCn. For instance, the first driving stage SRC1 receives the first clock signal CKV, and the ripple discharge circuit RDC1 receives the second clock signal CKVB. The second driving stage SRC2 receives the second clock signal CKVB, and the ripple discharge circuit RDC2 receives the first clock signal CKV. Each of the ripple discharge circuits RDC1 to RDCn discharges a ripple voltage of the gate lines GL1 to GLn to the first ground voltage VSS1 in synchronization with the clock signal (the first clock signal CKV or the second clock signal CKVB) applied thereto.

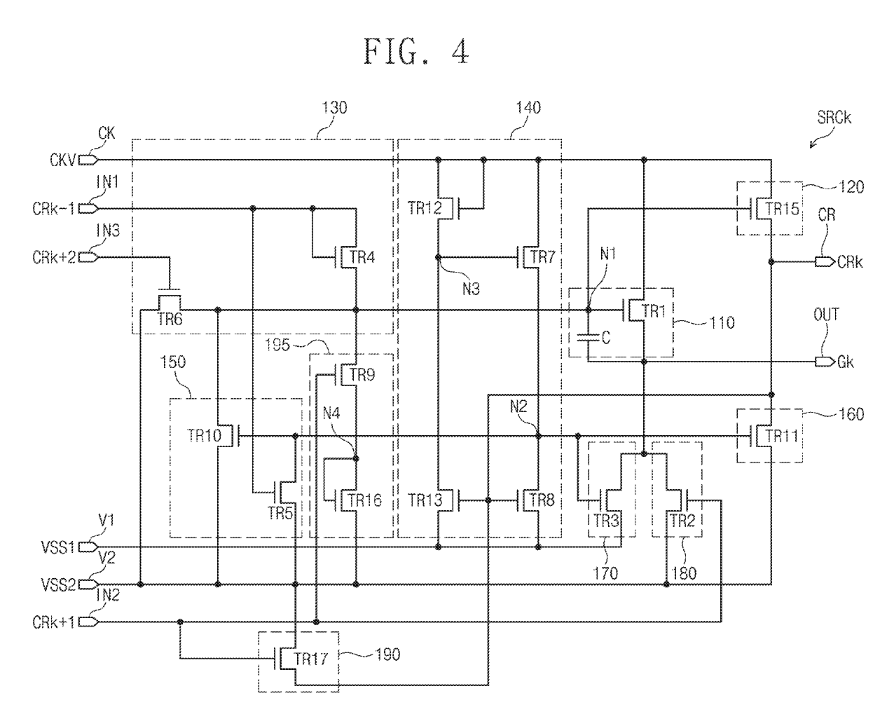

FIG. 4 is a circuit diagram showing a driving stage of FIG. 3 according to an exemplary embodiment of the inventive concept.

FIG. 4 shows the k-th driving stage SRCk (where “k” is a positive integer number), among the driving stages SRC1 to SRCn of FIG. 3, as a representative example. Each of the driving stages SRC1 to SRCn shown in FIG. 3 may have substantially the same circuit configuration as that of the k-th driving stage SRCk.

Referring to FIG. 4, the k-th driving stage SRCk includes a first output circuit 110, a second output circuit 120, a control circuit 130, a discharge hold circuit 140, a first discharge circuit 150, a second discharge circuit 160, a third discharge circuit 170, a first pull-down circuit 180, a second pull-down circuit 190, and a third pull-down circuit 195.

The first output circuit 110 outputs a k-th gate signal Gk, and the second output circuit 120 outputs a k-th carry signal CRk. The first pull-down circuit 180 pulls down the output terminal OUT to the second ground voltage VSS2 connected to the second voltage terminal V2, and the second pull-down circuit 190 pulls down the carry terminal CR to the second ground voltage VSS2 connected to the second voltage terminal V2. The control circuit 130 controls an operation of the first output circuit 110 and the second output circuit 120.

The circuit configuration of the k-th driving stage SRCk is as follows.

The first output circuit 110 includes a first output transistor TR1 and a capacitor C. The first output transistor TR1 includes a first electrode connected to the clock terminal CK, a control electrode connected to a first node N1, and a second electrode outputting the k-th gate signal Gk.

The second output circuit 120 includes a second output transistor TR15. The second output transistor TR15 includes a first electrode connected to the clock terminal CK, a control electrode connected to the first node N1, and a second electrode outputting the k-th carry signal CRk.

As shown in FIG. 3, the clock terminals CK of the driving stages SRC1, SRC3, . . . , SRCn−1 among the driving stages SRC1 to SRCn and the dummy driving stage SRCn+1 receive the first clock signal CKV. The clock terminals CK of the driving stages SRC2, SRC4, . . . , SRCn among the driving stages SRC1 to SRCn and the dummy driving stage SRCn+2 receive the second clock signal CKVB. The first clock signal CKV and the second clock signal CKVB are signals complementary to each other. In other words, the first clock signal CKV and the second clock signal CKVB have a phase difference of about 180 degrees.

The control circuit 130 turns on the first and second output transistors TR1 and TR15 in response to a (k−1)th carry signal CRk−1 output from the previous driving stage SRCk−1 and applied to the first input terminal IN1. The control circuit 130 turns off the first and second output transistors TR1 and TR15 in response to a (k+2)th carry signal CRk+2 output from the driving stage SRCk+2 following the next driving stage and applied to the third input terminal IN3.

The control circuit 130 includes fourth and sixth transistors TR4 and TR6. The fourth transistor TR4 includes a first electrode connected to the first input terminal IN1, a second electrode connected to the first node N1, and a control electrode connected to the first input terminal IN1. The sixth transistor TR6 includes a first electrode connected to the first node N1, a second electrode connected to the second voltage terminal V2, and a control electrode connected to the third input terminal IN3.

The discharge hold circuit 140 applies the first clock signal CKV from the clock terminal CK to a second node N2. The discharge hold circuit 140 includes seventh, eighth, twelfth, and thirteenth transistors TR7, TR8, TR12, and TR13. The seventh transistor TR7 includes a first electrode connected to the clock terminal CK, a second electrode connected to the second node N2, and a control electrode connected to a third node N3. The twelfth transistor TR12 includes a first electrode connected to the clock terminal CK, a second electrode connected to the third node N3, and a control electrode connected to the clock terminal CK. The eighth transistor TR8 includes a first electrode connected to the second node N2, a second electrode connected to the first voltage terminal V1, and a control electrode connected to the carry terminal CR. The thirteenth transistor TR13 includes a first electrode connected to the third node N3, a second electrode connected to the first voltage terminal V1, and a control electrode connected to the carry terminal CR.

The first discharge circuit 150 discharges the second node N2 to the second ground voltage VSS2 in response to the (k−1)th carry signal CRk−1 and discharges the first node N1 to the second ground voltage VSS2 in response to a signal of the second node N2. The first discharge circuit 150 includes a fifth transistor TR5 and a tenth transistor TR10. The fifth transistor TR5 includes a first electrode connected to the second node N2, a second electrode connected to the second voltage terminal V2, and a control electrode connected to the first input terminal IN1. The tenth transistor TR10 includes a first electrode connected to the first node N1, a second electrode connected to the second voltage terminal V2, and a control electrode connected to the second node N2.

The second discharge circuit 160 discharges the carry terminal CR to the second ground voltage VSS2 in response to a signal of the second node N2. The second discharge circuit 160 includes an eleventh transistor TR11 including a first electrode connected to the carry terminal CR, a second electrode connected to the second voltage terminal V2, and a control electrode connected to the second node N2.

The third discharge circuit 170 discharges the output terminal OUT to the first ground voltage VSS1 in response to the signal of the second node N2. The third discharge circuit 170 includes a third transistor TR3 including a first electrode connected to the output terminal OUT, a second electrode connected to the first voltage terminal V1, and a control electrode connected to the second node N2.

The first pull-down circuit 180 discharges the output terminal OUT to the second ground voltage VSS2 in response to the (k+1)th carry signal CRk+1 provided through the second input terminal IN2. The first pull-down circuit 180 includes a second transistor TR2 including a first electrode connected to the output terminal OUT, a second electrode connected to the second voltage terminal V2, and a control electrode connected to the second input terminal IN2.

The second pull-down circuit 190 discharges the carry terminal CR to the second ground voltage VSS2 in response to the (k+1)th carry signal CRk+1 provided through the second input terminal IN2. The second pull-down circuit 190 includes a seventeenth transistor TR17 including a first electrode connected to the carry terminal CR, a second electrode connected to the second voltage terminal V2, and a control electrode connected to the second input terminal IN2.

The third pull-down circuit 195 discharges the first node N1 to the second ground voltage VSS2 in response to the (k+1)th carry signal CRk+1. The third pull-down circuit 195 includes a ninth transistor TR9 and a sixteenth transistor TR16. The ninth transistor TR9 includes a first electrode connected to the first node N1, a second electrode connected to a fourth node N4, and a control electrode connected to the second input terminal IN2. The sixteenth transistor TR16 includes a first electrode connected to the fourth node N4, a second electrode connected to the second voltage terminal V2, and a control electrode connected to the fourth node N4.

In the present exemplary embodiment, the transistors included in the driving stages SRC1 to SRCn shown in FIG. 3 are formed together with thin film transistors of the pixels PX11 to PXnm of the display panel DP shown in FIGS. 1 and 2 through a same process. Amorphous silicon or an oxide semiconductor such as indium gallium zinc oxide (IGZO) may be used as a semiconductor material for a channel layer of the thin film transistor of the pixels PX11 to PXnm and the transistor of each driving stage.

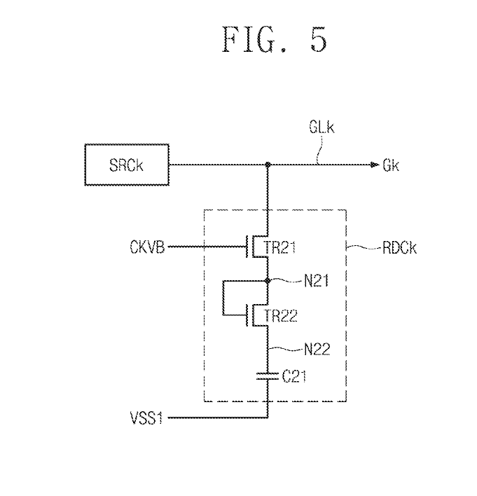

FIG. 5 is a circuit diagram showing a ripple discharge circuit according to an exemplary embodiment of the inventive concept.

FIG. 5 shows a k-th ripple discharge circuit RDCk (where k is a positive integer number) among the ripple discharge circuits RDC1 to RDCn of FIG. 3 as a representative example. Each of the ripple discharge circuits RDC1 to RDCn shown in FIG. 3 may have substantially the same circuit configuration as that of the k-th ripple discharge circuit RDCk.

Referring to FIG. 5, the k-th ripple discharge circuit RDCk is connected to a k-th gate line GLk and receives the second clock signal CKVB and the first ground voltage VSS1. In the exemplary embodiment shown in FIG. 4, the k-th driving stage SRCk receives the first clock signal CKV, and thus the k-th ripple discharge circuit RDCk receives the second clock signal CKVB that is complementary to the first clock signal CKV. In a case that the k-th driving stage SRCk receives the second clock signal CKVB, the k-th ripple discharge circuit RDCk receives the first clock signal CKV.

The k-th ripple discharge circuit RDCk discharges a voltage of the k-th gate line GLk to a voltage corresponding to the first ground voltage VSS1 when the second clock signal CKVB has a first level (e.g., a high level) and a voltage level of the k-th gate signal Gk output to the k-th gate line GLk is higher than the voltage corresponding to the first ground voltage VSS1.

The k-th ripple discharge circuit RDCk includes a first switching unit TR21, a second switching unit TR22, and a capacitor C21. The first switching unit TR21 electrically connects the k-th gate line GLk to a node N21 in response to the second clock signal CKVB. The second switching unit TR22 electrically connects the node N21 to a node N22 in response to a signal of the node N21. The capacitor C21 is connected between the node N22 and a node to which the first ground voltage VSS1 is applied.

In the present exemplary embodiment, the first switching unit TR21 is an NMOS transistor, and the second switching unit TR22 is a diode-connected NMOS transistor.

The first switching unit TR21 is connected between the k-th gate line GLk and the node N21. The first switching unit TR21 includes a control electrode receiving the second clock signal CKVB. The second switching unit TR22 is connected between the node N21 and the node N22. The second switching unit TR22 includes a control electrode connected to the node N21.

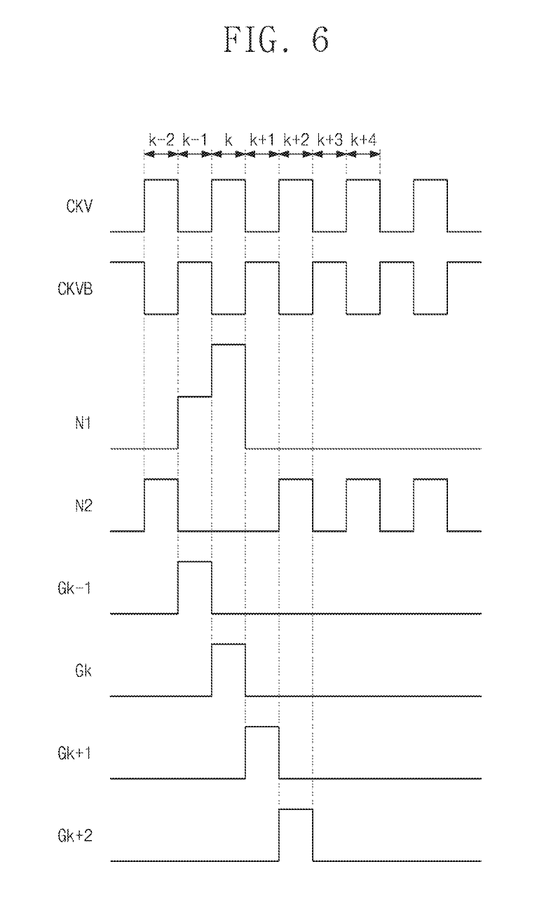

FIG. 6 is a timing diagram showing an operation of the driving stage of FIG. 4 and the ripple discharge circuit of FIG. 5 according to an exemplary embodiment of the inventive concept.

Referring to FIGS. 3 to 6, the first clock signal CKV and the second clock signal CKVB have substantially the same frequency as each other and different phases from each other. In the present exemplary embodiment, the first clock signal CKV and the second clock signal CKVB are signals complementary to each other.

When the (k−1)th carry signal CRk−1 is transited to the high level in a (k−1)th clock period k−1, the fourth transistor TR4 is turned on, and the voltage level of the first node N1 rises. When the first clock signal CKV is transited to the high level in a k-th clock period k, the first output transistor TR1 is turned on, and the voltage of the first node N1 is boosted by the capacitor C. In this case, the k-th gate signal Gk is output through the output terminal OUT. When the second output transistor TR15 is turned on by the boosted voltage of the first node N1, the k-th carry signal CRk is output through the carry terminal CR.

When the first clock signal CKV is transited to the low level in a (k+1)th clock period k+1, the first output transistor TR1 and the second output transistor TR15 are turned off.

Then, when the (k+1)th carry signal CRk+1 is transited to the high level, the second transistor TR2 of the first pull-down circuit 180 is turned on, and the k-th gate signal Gk output through the output terminal OUT is discharged to the second ground voltage VSS2. When the seventeenth transistor T17 of the second pull-down circuit 190 is turned on in response to the (k+1)th carry signal CRk+1 at the high level, the k-th gate signal Gk output through the output terminal OUT is discharged to the second ground voltage VSS2. When the ninth transistor TR9 and the sixteenth transistor T16 are turned on in response to the (k+1)th gate signal Gk+1 at the high level, the first node N1 is discharged to the second ground voltage VSS2.

Then, when a (k+2)th gate signal Gk+2 is transited to the high level in a (k+2)th clock period k+2, the sixth transistor TR6 is turned on, and thus the first node N1 is maintained in the second ground voltage VSS2.

Meanwhile, when the first clock signal CKV has the high level in the (k+2)th clock period k+2, the second node N2 is transited to the high level. When the second node N2 is transited to the high level, the third transistor TR3 is turned on, and thus the output terminal OUT is maintained in the first ground voltage VSS1. Similarly, when the second node N2 is transited to the high level, the eleventh transistor TR11 is turned on, and thus the carry terminal CR is maintained in the second ground voltage VSS2.

The gate signals G1 to Gn may be maintained lower than a predetermined level in a period. For example, the gate signals G1 to Gn are maintained in a gate-off voltage level (e.g., the level of the first ground voltage VSS1 in the present exemplary embodiment), except for a period in which the gate signals G1 to Gn are maintained in a gate-on voltage level. The pixels PX11 to PXnm shown in FIG. 1 may be prevented from malfunctioning when the gate signals G1 to Gn are maintained in the gate-off voltage level.

When the transistors TR1 to TR17 shown in FIG. 4 are operated for a long time at a high temperature, a threshold voltage of the transistors TR1 to TR17 may vary. In the case that the threshold voltage of the transistors TR1 to TR17 varies, the transistors TR1 to TR17 may be turned on weakly, and thus the weakly turned-on transistors TR1 to TR17 may cause the voltage level of the gate signals G1 to Gn to rise.

In a case that the voltage level of the gate signals G1 to Gn increases in a period where the gate signals G1 to Gn are maintained in the gate-off voltage level, the ripple discharge circuits RDC1 to RDCn according to the present exemplary embodiment may discharge the increased ripple voltage.

Referring to FIGS. 5 and 6 again, when the voltage level of the k-th gate signal Gk is higher than a voltage level of one end of the capacitor C21, e.g., the voltage level of the node N22, in a (k+3)th clock period k+3 in which the second clock signal CKVB has the high level, electric charges of the k-th gate line GLk may be charged in the capacitor C21 through the first and second switching units TR21 and TR22 and then discharged.

The above-described discharge operation is repeatedly performed in the (k+1)th and the (k+3)th clock periods where the second clock signal CKVB has the high level. Thus, the voltage level of the gate signals G1 to Gn may be prevented from abnormally increasing in a period where the gate signals G1 to Gn are maintained in the gate-off voltage level within one frame. Accordingly, reliability of the gate driving circuit 100 is increased.

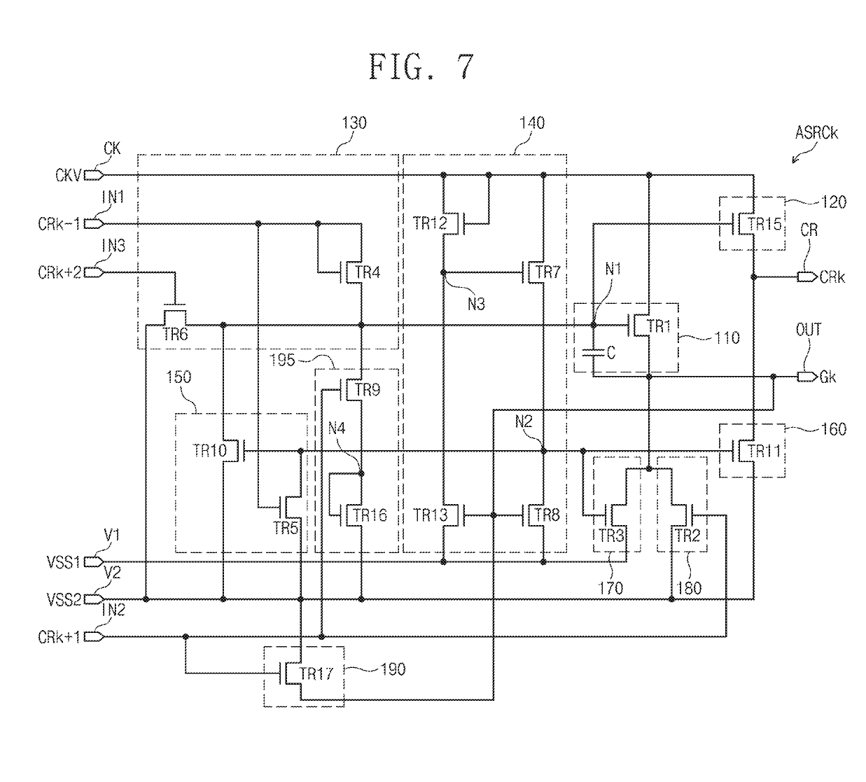

FIG. 7 is a circuit diagram showing a driving stage according to an exemplary embodiment of the inventive concept.

Since a k-th driving stage ASRCk (where k is a positive integer number) shown in FIG. 7 has a similar circuit configuration to that of the k-th driving stage SRCk shown in FIG. 4, the same elements will be assigned the same reference numerals, and detailed descriptions of the same elements will be omitted to avoid redundancy.

In FIG. 7, control electrodes of transistors TR13 and TR8 included in the discharge hold circuit 140 of the k-th driving stage ASRCk are connected to the output terminal OUT. The output terminal OUT of the k-th driving stage ASRCk may be connected to the k-th ripple discharge circuit RDCk shown in FIG. 5.

The transistors TR13 and TR8 are operated in response to the k-th gate signal Gk from which a ripple voltage is removed by the k-th ripple discharge circuit RDCk. Thus, the transistors TR13 and TR8 may be prevented from being abnormally turned on and the voltage level of the second node N2 may be prevented from being discharged in a period where the second clock signal CKVB has the high level.

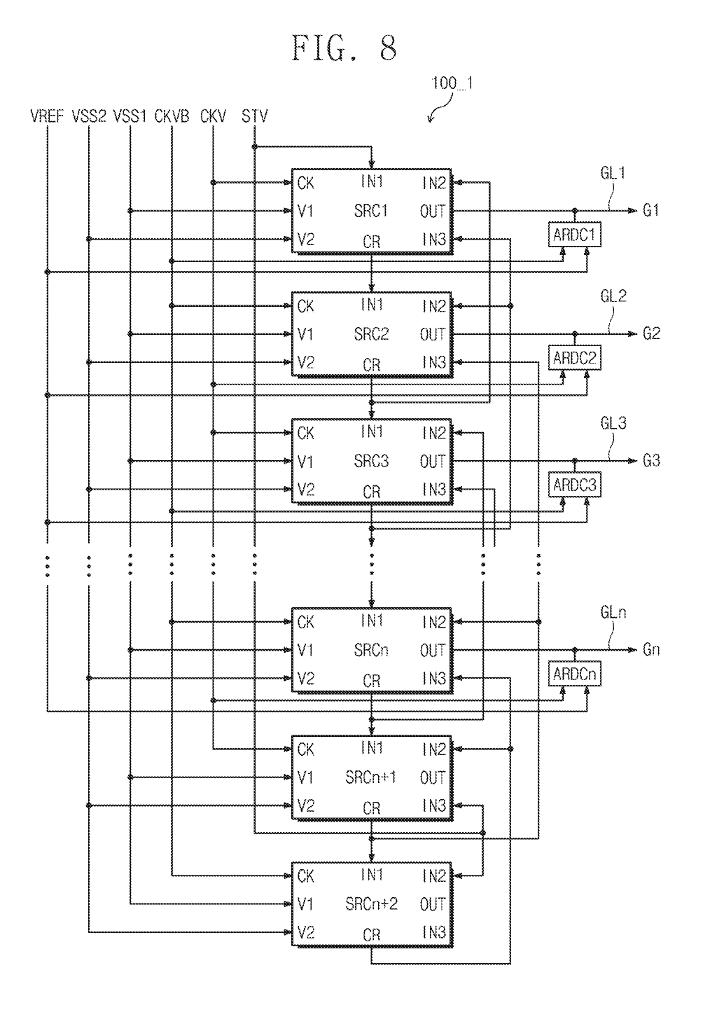

FIG. 8 is a block diagram showing a gate driving circuit according to an exemplary embodiment of the inventive concept.

Since a gate driving circuit 100_1 shown in FIG. 8 has a similar circuit configuration to that of the gate driving circuit 100 shown in FIG. 3, the same elements will be assigned the same reference numerals, and detailed descriptions of the same elements will be omitted to avoid redundancy.

Referring to FIG. 8, the gate driving circuit 100_1 includes the plurality of driving stages SRC1 to SRCn, the dummy driving stages SRCn+1 and SRCn+2, and a plurality of ripple discharge circuits ARDC1 to ARDCn.

The ripple discharge circuits ARDC1 to ARDCn are connected to the gate lines GL1 to GLn, respectively. The ripple discharge circuits ARDC1 to ARDCn may discharge the ripple voltage of the gate lines GL1 to GLn.

Each of the ripple discharge circuits ARDC1 to ARDCn receives the clock signal (the first clock signal CKV or the second clock signal CKVB) and a reference voltage VREF from the driving controller 300 shown in FIG. 1. The reference voltage VREF may have a voltage level different from that of the first ground voltage VSS1 and the second ground voltage VSS2.

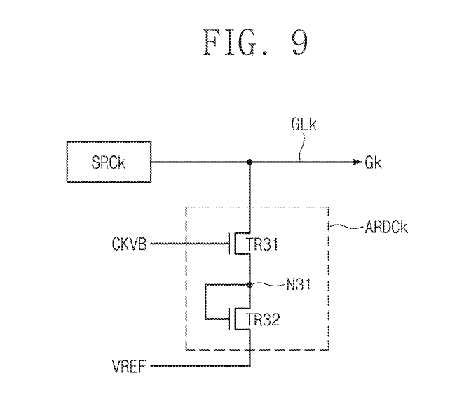

FIG. 9 is a circuit diagram showing a ripple discharge circuit according to an exemplary embodiment of the inventive concept.

Referring to FIG. 9, a k-th ripple discharge circuit ARDCk (where k is a positive integer number), among the ripple discharge circuits ARDC1 to ARDCn of FIG. 8, includes a first switching unit TR31 and a second switching unit TR32. The first switching unit TR31 electrically connects the k-th gate line GLk to a node N31 in response to the second clock signal CKVB. The second switching unit TR32 discharges the node N31 to the reference voltage VREF level in response to a signal of the node N31.

In the present exemplary embodiment, the first switching unit TR31 is an NMOS transistor, and the second switching unit TR32 is a diode-connected NMOS transistor.

The first switching unit TR31 is connected between the k-th gate line GLk and the node N31. The first switching unit TR31 includes a control electrode receiving the second clock signal CKVB. The second switching unit TR32 is connected between the node N31 and a node to which the reference voltage VREF is applied. The second switching unit TR32 includes a control electrode connected to the node N31.

When the second clock signal CKVB has the high level, the first switching unit TR31 is turned on. When the voltage level of the node N31 rises to turn on the second switching unit TR32, the voltage level of the k-th gate signal Gk may be discharged to the reference voltage VREF.

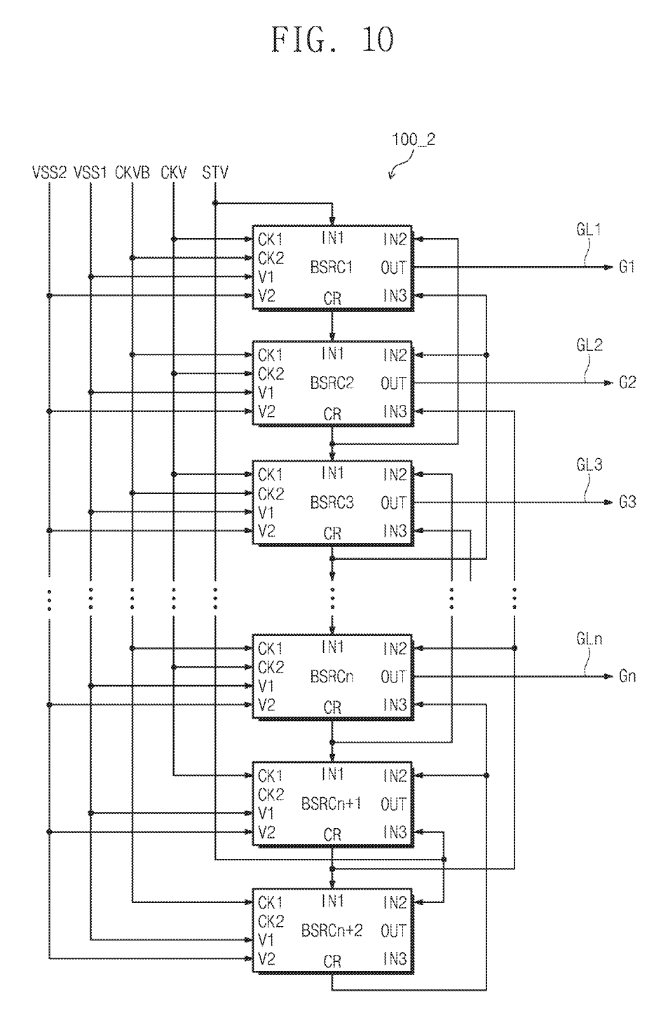

FIG. 10 is a block diagram showing a gate driving circuit according to an exemplary embodiment of the inventive concept.

Since a gate driving circuit 100_2 shown in FIG. 10 has a similar circuit configuration to that of the gate driving circuit 100 shown in FIG. 3, the same elements will be assigned the same reference numerals, and detailed descriptions of the same elements will be omitted to avoid redundancy.

Referring to FIG. 10, the gate driving circuit 100_2 includes a plurality of driving stages BSRC1 to BSRCn and dummy driving stages BSRCn+1 and BSRCn+2.

The driving stages BSRC1 to BSRCn and the dummy driving stages BSRCn+1 and BSRCn+2 are connected to each other one after another to allow each driving stage to be driven in response to a carry signal output from a previous driving stage and a carry signal output from a next driving stage.

Each of the driving stages BSRC1 to BSRCn receives the first clock signal CKV, the second clock signal CKVB, the first ground voltage VSS1, and the second ground voltage VSS2 from the driving controller 300 shown in FIG. 1. The driving stage BSRC1 and the dummy driving stages BSRCn+1 and BSRCn+2 further receive the start signal STV.

Each of the driving stages BSRC1 to BSRCn and the dummy driving stages BSRCn+1 and BSRCn+2 includes input terminals IN1, IN2, and IN3, the output terminal OUT, the carry terminal CR, a first clock terminal CK1, a second clock terminal CK2, the first voltage terminal V1, and the second voltage terminal V2.

Each of the driving stages SRC1 to SRCn and the dummy driving stages SRCn+1 and SRCn+2 shown in FIG. 3 receives one of the first clock signal CKV and the second clock signal CKVB. However, each of the driving stages BSRC1 to BSRCn and the dummy driving stages BSRCn+1 and BSRCn+2 shown in FIG. 10 receives both of the first clock signal CKV and the second clock signal CKVB.

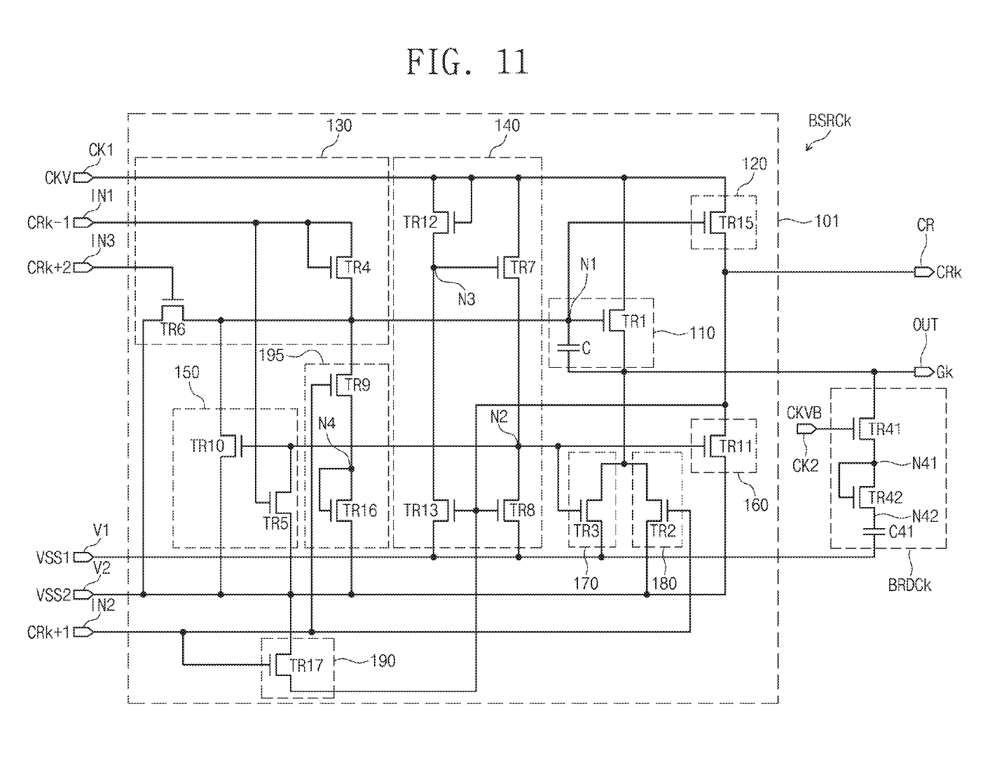

FIG. 11 is a circuit diagram showing a driving stage according to an exemplary embodiment of the inventive concept.

FIG. 11 shows a k-th driving stage BSRCk (where k is a positive integer number) among the driving stages BSRC1 to BSRCn of FIG. 10 as a representative example. Each of the driving stages BSRC1 to BSRCn shown in FIG. 10 may have substantially the same circuit configuration as that of the k-th driving stage BSRCk.

Referring to FIG. 11, the k-th driving stage BSRCk includes a driving circuit 101 and a ripple discharge circuit BRDCk. The driving circuit 101 includes the first output circuit 110, the second output circuit 120, the control circuit 130, the discharge hold circuit 140, the first discharge circuit 150, the second discharge circuit 160, the third discharge circuit 170, the first pull-down circuit 180, the second pull-down circuit 190, and the third pull-down circuit 195.

The circuits 110, 120, 130, 140, 150, 160, 170, 180, 190, and 195 of the driving circuit 101 shown in FIG. 11 have substantially the same structure as that of the circuits 110, 120, 130, 140, 150, 160, 170, 180, 190, and 195 of the k-th driving stage SRCk shown in FIG. 4.

The ripple discharge circuit BRDCk of the k-th driving stage BSRCk shown in FIG. 11 has substantially the same circuit configuration as that of the ripple discharge circuit RDCk shown in FIG. 5. The ripple discharge circuit BRDCk includes a first switching unit TR41, a second switching unit TR42, and a capacitor C41. The first switching unit TR41 electrically connects the k-th gate line GLk to a node N41 in response to the second clock signal CKVB received through the second clock terminal CK2. The second switching unit TR42 electrically connects the node N41 to a node N42 in response to a signal of the node N41. The capacitor C41 is connected between the node N42 and the first voltage terminal V1.

In the present exemplary embodiment, the first switching unit TR41 is an NMOS transistor, and the second switching unit TR42 is a diode-connected NMOS transistor.

The first switching unit TR41 is connected between the k-th gate line GLk and the node N41. The first switching unit TR41 includes a control electrode connected to the second clock terminal CK2. The second switching unit TR42 is connected between the node N41 and the node N42. The second switching unit TR42 includes a control electrode connected to the node N41.

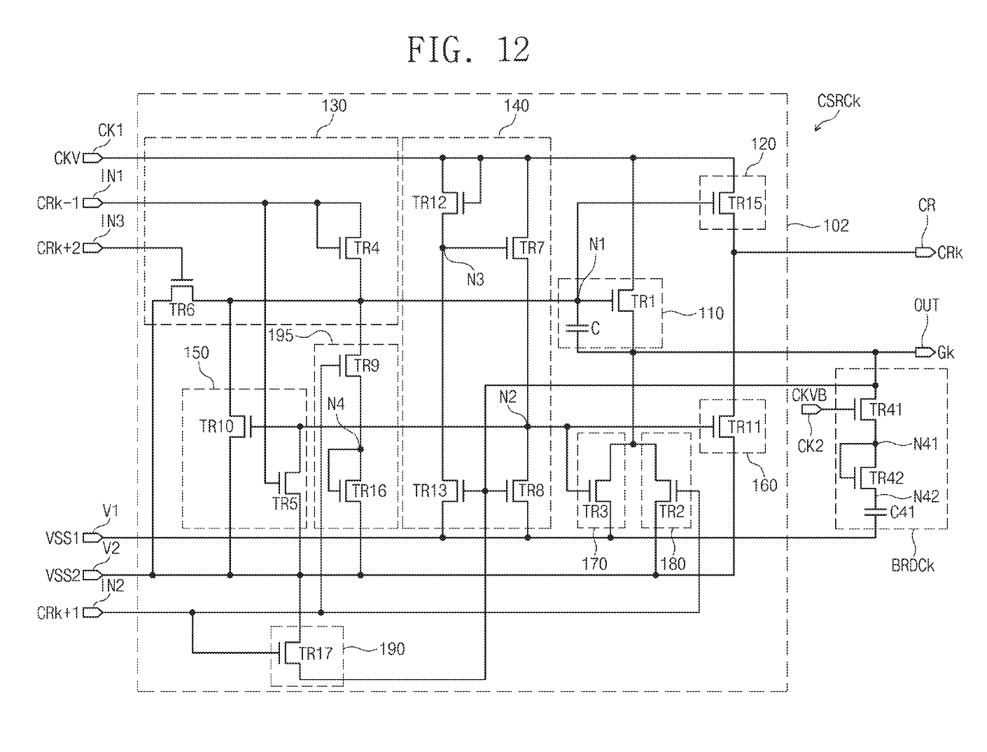

FIG. 12 is a circuit diagram showing a driving stage according to an exemplary embodiment of the inventive concept.

As shown in FIG. 12, a k-th driving stage CSRCk (where k is a positive integer number) includes a driving circuit 102 and the ripple discharge circuit BRDCk. Since the k-th driving stage CSRCk shown in FIG. 12 has a similar circuit configuration to that of the k-th driving stage BSRCk shown in FIG. 11, the same elements will be assigned the same reference numerals, and detailed descriptions of the same elements will be omitted to avoid redundancy.

The control electrodes of the transistors TR13 and TR8 included in the discharge hold circuit 140 of the k-th driving stage CSRCk are connected to the output terminal OUT. The transistors TR13 and TR8 are operated in response to the k-th gate signal Gk from which a ripple voltage is removed by the ripple discharge circuit BRDCk. Thus, the transistors TR13 and TR8 may be prevented from being abnormally turned on, and the voltage level of the second node N2 may be prevented from being discharged in the period where the second clock signal CKVB has the high level.

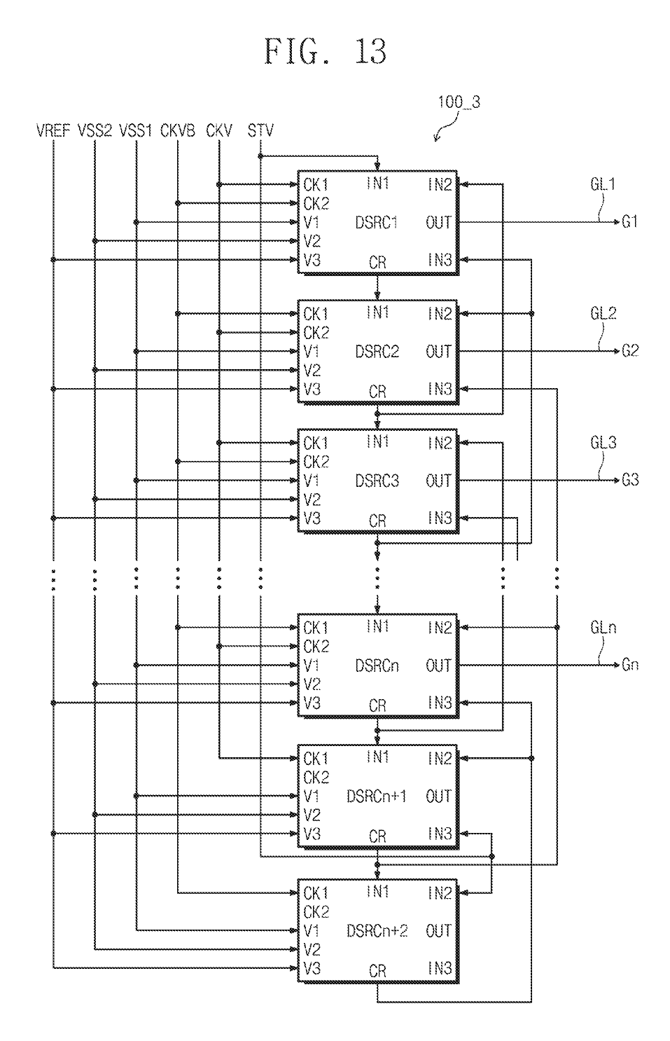

FIG. 13 is a block diagram showing a gate driving circuit according to an exemplary embodiment of the inventive concept.

Since a gate driving circuit 100_3 shown in FIG. 13 has a similar circuit configuration to that of the gate driving circuit 100_2 shown in FIG. 10, the same elements will be assigned the same reference numerals, and detailed descriptions of the same elements will be omitted to avoid redundancy.

Referring to FIG. 13, the gate driving circuit 100_3 includes a plurality of driving stages DSRC1 to DSRCn and dummy driving stages DSRCn+1 and DSRCn+2.

The driving stages DSRC1 to DSRCn and the dummy driving stages DSRCn+1 and DSRCn+2 are connected to each other one after another to allow each driving stage to be driven in response to a carry signal output from a previous driving stage and a carry signal output from a next driving stage.

Each of the driving stages DSRC1 to DSRCn receives the first clock signal CKV, the second clock signal CKVB, the first ground voltage VSS1, the second ground voltage VSS2, and the reference voltage VREF from the driving controller 300 shown in FIG. 1. The driving stage DSRC1 and the dummy driving stages DSRCn+1 and DSRCn+2 further receive the start signal STV.

Each of the driving stages DSRC1 to DSRCn and the dummy driving stages DSRCn+1 and DSRCn+2 includes the input terminals IN1, IN2, and IN3, the output terminal OUT, the carry terminal CR, the first clock terminal CK1, the second clock terminal CK2, the first voltage terminal V1, the second voltage terminal V2, and a third voltage terminal V3.

In contrast to the driving stages BSRC1 to BSRCn and the dummy driving stages BSRCn+1 and BSRCn+2 shown in FIG. 10, each of the driving stages DSRC1 to DSRCn and the dummy driving stages DSRCn+1 and DSRCn+2 shown in FIG. 13 further receives the reference voltage VREF through the third voltage terminal V3.

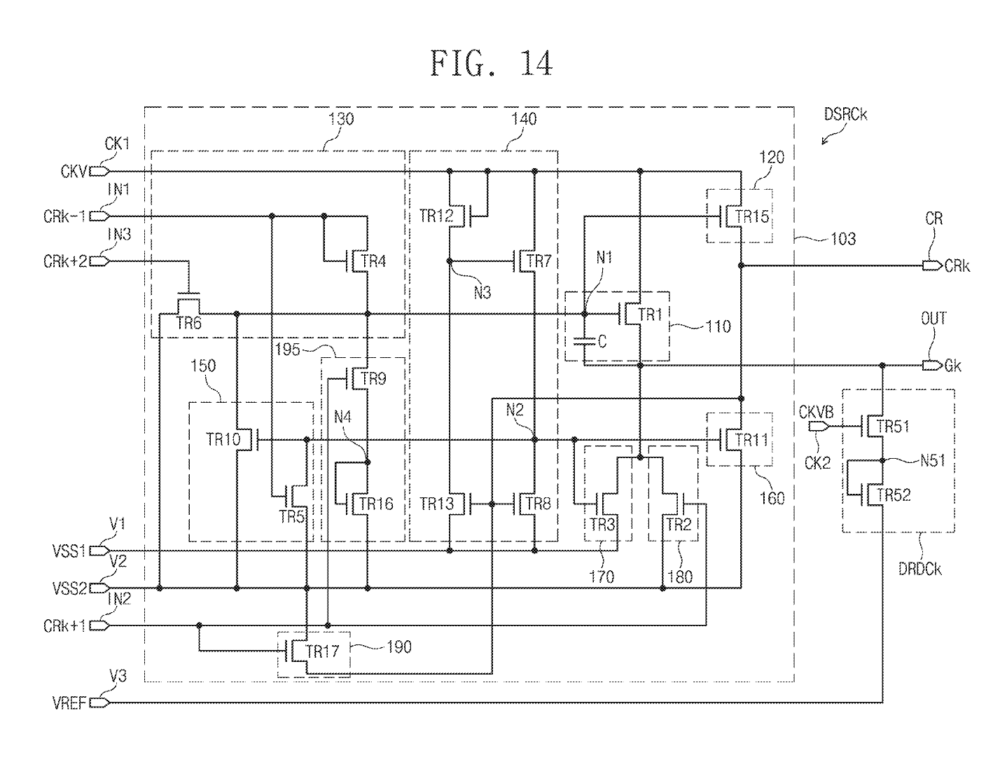

FIG. 14 is a circuit diagram showing a driving stage according to an exemplary embodiment of the inventive concept.

FIG. 14 shows a k-th driving stage DSRCk (where k is a positive integer number) among the driving stages DSRC1 to DSRCn of FIG. 13 as a representative example. Each of the driving stages DSRC1 to DSRCn shown in FIG. 13 may have substantially the same circuit configuration as that of the k-th driving stage DSRCk.

Referring to FIG. 14, the k-th driving stage DSRCk includes a driving circuit 103 and a ripple discharge circuit DRDCk. The driving circuit 103 includes the first output circuit 110, the second output circuit 120, the control circuit 130, the discharge hold circuit 140, the first discharge circuit 150, the second discharge circuit 160, the third discharge circuit 170, the first pull-down circuit 180, the second pull-down circuit 190, and the third pull-down circuit 195.

The circuits 110, 120, 130, 140, 150, 160, 170, 180, 190, and 195 of the driving circuit 103 shown in FIG. 14 have substantially the same structure as that of the circuits 110, 120, 130, 140, 150, 160, 170, 180, 190, and 195 of the driving circuit 101 shown in FIG. 11. The ripple discharge circuit DRDCk of the k-th driving stage DSRCk shown in FIG. 14 has substantially the same circuit configuration as that of the ripple discharge circuit ARDCk shown in FIG. 9.

The ripple discharge circuit DRDCk includes a first switching unit TR51 and a second switching unit TR52. The first switching unit TR51 electrically connects the k-th gate line GLk to a node N51 in response to the second clock signal CKVB. The second switching unit TR52 discharges the node N51 to the reference voltage VREF level in response to a signal of the node N51.

In the present exemplary embodiment, the first switching unit TR51 is an NMOS transistor, and the second switching unit TR52 is a diode-connected NMOS transistor.

The first switching unit TR51 is connected between the k-th gate line GLk and the node N51. The first switching unit TR51 includes a control electrode connected to the second clock terminal CK2. The second switching unit TR52 is connected between the node N51 and the third voltage terminal V3. The second switching unit TR52 includes a control electrode connected to the node N51.

When the second clock signal CKVB has the high level, the first switching unit TR51 is turned on. When the voltage level of the node N51 rises to turn on the second switching unit TR52, the voltage level of the k-th gate signal Gk is discharged to the reference voltage VREF.

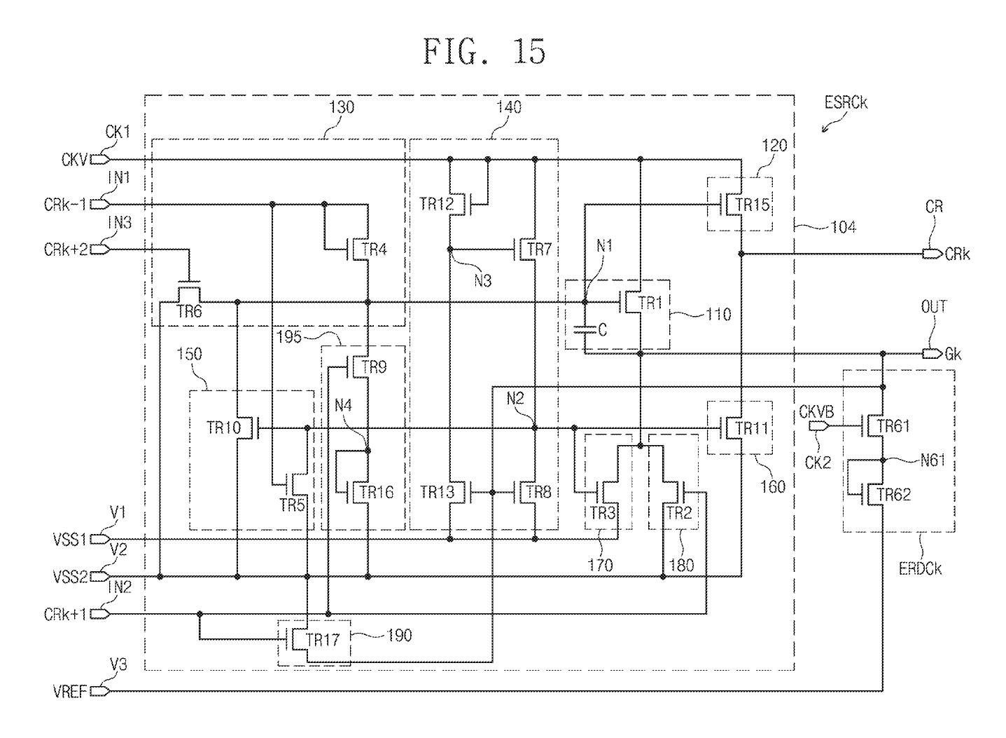

FIG. 15 is a circuit diagram showing a driving stage according to an exemplary embodiment of the inventive concept.

In FIG. 15, a k-th driving stage ESRCk (where k is a positive integer number) includes a driving circuit 104 and a ripple discharge circuit ERDCk. Since the k-th driving stage ESRCk shown in FIG. 15 has a similar circuit configuration to that of the k-th driving stage DSRCk shown in FIG. 14, the same elements will be assigned the same reference numerals, and detailed descriptions of the same elements will be omitted to avoid redundancy.

The control electrodes of the transistors TR13 and TR8 included in the discharge hold circuit 140 of the driving circuit 104 shown in FIG. 15 are connected to the output terminal OUT. The transistors TR13 and TR8 are operated in response to the k-th gate signal Gk from which a ripple voltage is removed by the ripple discharge circuit ERDCk. Thus, the transistors TR13 and TR8 may be prevented from being abnormally turned on, and the voltage level of the second node N2 may be prevented from being discharged in a period where the second clock signal CKVB has the high level.

As described above, according to exemplary embodiments of the inventive concept, the gate driving circuit periodically removes the ripple voltage generated in a period where the gate signal is required to be maintained in a ground voltage level. Thus, the reliability of the gate driving circuit is increased.

While the inventive concept has been shown and described with reference to exemplary embodiments thereof, it will be understood by those of ordinary skill in the art that various changes in form and details may be made thereto without departing from the spirit and scope of the inventive concept as set forth by the following claims.

What is claimed is:

1. A gate driving circuit comprising:
a plurality of driving stages configured to apply gate signals to a plurality of gate lines of a display panel; and
a plurality of ripple discharge circuits configured to discharge a ripple voltage of the plurality of gate lines,
wherein a k-th driving stage, among the plurality of driving stages, outputs a k-th gate signal to a k-th gate line, among the plurality of gate lines, in synchronization with a first clock signal,
a k-th ripple discharge circuit, among the plurality of ripple discharge circuits and corresponding to the k-th driving stage, discharges a ripple voltage of the k-th gate line to a first voltage in synchronization with a second clock signal complementary to the first clock signal, and
k is a natural number greater than 1.

2. The gate driving circuit of claim 1, wherein the k-th ripple discharge circuit discharges the ripple voltage of the k-th gate signal to the first voltage when the second clock signal has a first level and the k-th gate signal is higher than a level of the first voltage.

3. The gate driving circuit of claim 1, wherein the k-th ripple discharge circuit comprises:
a first switching unit electrically connecting the k-th gate line to a first node in response to the second clock signal;
a second switching unit electrically connecting the first node and a second node in response to a signal of the first node; and
a capacitor connected between the second node and a node to which the first voltage is applied.

4. The gate driving circuit of claim 2, wherein the k-th ripple discharge circuit comprises:
a first transistor connected between the k-th gate line and a first node and comprising a control electrode configured to receive the second clock signal;
a second transistor connected between the first node and a second node and comprising a control electrode connected to the first node; and
a capacitor connected between the second node and a node to which the first voltage is applied.

5. The gate driving circuit of claim 1, wherein the k-th ripple discharge circuit comprises:
a first switching unit electrically connecting the k-th gate line to a first node in response to the second clock signal; and
a second switching unit discharging the first node to the first voltage in response to a signal of the first node.

6. The gate driving circuit of claim 1, wherein the k-th driving stage further receives a (k−1)th carry signal from a (k−1)th driving stage, a (k+1)th carry signal from a (k+1)th driving stage, a (k+2)th carry signal from a (k+2)th driving stage, and a second voltage, and further outputs a k-th carry signal.

7. The gate driving circuit of claim 6, wherein the k-th driving stage comprises:
a first output circuit configured to output the first clock signal as the k-th gate signal in response to a signal of a first node during a k-th clock period of the first clock signal; and
a second output circuit configured to output the first clock signal as the k-th carry signal in response to the signal of the first node during the k-th clock period of the first clock signal.

8. The gate driving circuit of claim 7, wherein the k-th driving stage further comprises:
a control circuit configured to apply the (k−1)th carry signal to the first node in response to the (k−1)th carry signal and discharge the first node to the second voltage in response to the (k+2)th carry signal;
a discharge hold circuit configured to apply the first clock signal to a second node in response to the first clock signal and the k-th carry signal;
a first discharge circuit configured to discharge the first node and the second node to the second voltage in response to the (k−1)th carry signal;
a second discharge circuit configured to discharge the k-th carry signal to the second voltage in response to a signal of the second node;
a third discharge circuit configured to discharge the k-th gate signal to the first voltage in response to the signal of the second node; and
a pull-down circuit configured to discharge the k-th carry signal to the second voltage in response to the (k+1)th carry signal.

9. The gate driving circuit of claim 7, wherein the k-th driving stage further comprises:
a control circuit configured to apply the (k−1)th carry signal to the first node in response to the (k−1)th carry signal and discharge the first node to the second voltage in response to the (k+2)th carry signal;
a discharge hold circuit configured to apply the first clock signal to a second node in response to the first clock signal and the k-th gate signal;
a first discharge circuit configured to discharge the first node and the second node to the second voltage in response to the (k−1)th carry signal;
a second discharge circuit configured to discharge the k-th carry signal to the second voltage in response to a signal of the second node;
a third discharge circuit configured to discharge the k-th gate signal to the first voltage in response to the signal of the second node; and
a pull-down circuit configured to discharge the k-th gate signal to the second voltage in response to the (k+1)th carry signal.

10. A gate driving circuit comprising:
a plurality of driving stages configured to apply gate signals to a plurality of gate lines of a display panel,
wherein a k-th driving stage (where k is a natural number greater than 1), among the plurality of driving stages, comprises:
a driving circuit configured to output a k-th gate signal to a k-th gate line, among the plurality of gate lines, in synchronization with a first clock signal; and
a ripple discharge circuit configured to discharge a ripple voltage of the k-th gate line to a first voltage in synchronization with a second clock signal that is complementary to the first clock signal.

11. The gate driving circuit of claim 10, wherein the ripple discharge circuit discharges the ripple voltage of the k-th gate line to the first voltage when the second clock signal has a first level and a voltage of the k-th gate line is higher than a level of the first voltage.

12. The gate driving circuit of claim 10, wherein the ripple discharge circuit comprises:
a first switching unit electrically connecting the k-th gate line to a first node in response to the second clock signal;
a second switching unit electrically connecting the first node to a second node in response to a signal of the first node; and
a capacitor connected between the second node and a node to which the first voltage is applied.

13. The gate driving circuit of claim 10, wherein the ripple discharge circuit comprises:
a first transistor connected between the k-th gate line and a first node and comprising a control electrode configured to receive the second clock signal;
a second transistor connected between the first node and a second node and comprising a control electrode connected to the first node; and
a capacitor connected between the second node and a node to which the first voltage is applied.

14. The gate driving circuit of claim 13, wherein the driving circuit comprises:
a first output circuit configured to output the first clock signal as the k-th gate signal in response to a signal of a first node during a k-th clock period of the first clock signal; and
a second output circuit configured to output the first clock signal as a k-th carry signal in response to the signal of the first node during the k-th clock period of the first clock signal.

15. The gate driving circuit of claim 14, wherein the driving circuit further comprises:
a control circuit configured to apply one of the first clock signal and a second voltage to the first node in response to the first clock signal, a (k−1)th carry signal, and a (k+2)th carry signal;
a discharge hold circuit configured to apply the first clock signal to a second node in response to the first clock signal and the k-th carry signal;
a first discharge circuit configured to discharge the first node and the second node to the second voltage in response to the (k−1)th carry signal;
a second discharge circuit configured to discharge the k-th carry signal to the second voltage in response to a signal of the second node;
a third discharge circuit configured to discharge the k-th gate signal to the first voltage in response to the signal of the second node; and
a pull-down circuit configured to discharge the k-th carry signal to the second voltage in response to a (k+1)th carry signal.

16. The gate driving circuit of claim 14, wherein the driving circuit further comprises:
a control circuit configured to apply one of the first clock signal and a second voltage to the first node in response to the first clock signal, a (k−1)th carry signal, and a (k+2)th carry signal;
a discharge hold circuit configured to apply the first clock signal to a second node in response to the first clock signal and the k-th gate signal;
a first discharge circuit configured to discharge the first node and the second node to the second voltage in response to the (k−1)th carry signal;
a second discharge circuit configured to discharge the k-th carry signal to the second voltage in response to a signal of the second node;
a third discharge circuit configured to discharge the k-th gate signal to the second voltage in response to the signal of the second node; and
a pull-down circuit configured to discharge the k-th gate signal to the second voltage in response to a (k+1)th carry signal.

17. A display device comprising:
a display panel comprising a plurality of gate lines, a plurality of data lines, and a plurality of pixels each being connected to a corresponding gate line of the plurality of gate lines and a corresponding data line of the plurality of data lines;
a gate driving circuit comprising a plurality of driving stages configured to output gate signals to the plurality of gate lines; and
a data driving circuit configured to drive the plurality of data lines,
wherein a k-th driving stage (where k is a natural number greater than 1) among the plurality of driving stages comprises:
a driving circuit configured to output a k-th gate signal to a k-th gate line, among the plurality of gate lines, in synchronization with a first clock signal; and
a ripple discharge circuit configured to discharge a ripple voltage of the k-th gate line to a first voltage in synchronization with a second clock signal that is complementary to the first clock signal.

18. The display device of claim 17, wherein the ripple discharge circuit discharges the ripple voltage of the k-th gate line to the first voltage when the second clock signal has a first level and the voltage of the k-th gate line is higher than a level of the first voltage.

19. The display device of claim 17, wherein the ripple discharge circuit comprises:
a first switching unit electrically connecting the k-th gate line to a first node in response to the second clock signal;
a second switching unit electrically connecting the first node to a second node in response to a signal of the first node; and
a capacitor connected between the second node and a node to which the first voltage is applied.

20. The display device of claim 17, wherein the ripple discharge circuit comprises:
a first transistor connected between the k-th gate line and a first node and comprising a control electrode configured to receive the second clock signal;
a second transistor connected between the first node and a second node and comprising a control electrode connected to the first node; and
a capacitor connected between the second node and a node to which the first voltage is applied.
